(19) United States
(12) Patent Application Publication
(10) Pub. No.: US 2012/0012925 A1
(43) Pub. Date: Jan. 19, 2012

(54) SEMICONDUCTOR DEVICE AND METHOD FOR MANUFACTURING THE SAME

(75) Inventor: Tae Kyung OH, Yongin (KR)

(73) Assignee: Hynix Semiconductor Inc., Icheon (KR)

(21) Appl. No.: 12/979,324

(22) Filed: Dec. 27, 2010

(30) Foreign Application Priority Data
Jul. 15, 2010 (KR) 10-2010-0068375

(51) Int. Cl. H01L 29/78; H01L 21/3205

(52) U.S. Cl. 257/330; 438/586; 257/E29.262; 257/E21.294

(57) ABSTRACT

A semiconductor device and a method for manufacturing the same are provided. The method etches a gate metal material of a sidewall of the active region connected to the storage node contact deeper than a gate metal material of a sidewall of the active region connected to the bit line contact in a buried gate structure to prevent GILD and to reduce resistance of a buried gate, thereby improving refresh characteristics of the semiconductor device.

### CROSS-REFERENCES TO RELATED APPLICATIONS

Priority to Korean patent application number 10-2010-0068375, filed on Jul. 15, 2010, which is incorporated by reference in its entirety, is claimed.

### BACKGROUND OF THE INVENTION

The present invention relates to a semiconductor device and a method for manufacturing the same.

A semiconductor memory device includes a plurality of unit cells, each being composed of a capacitor and a transistor. The capacitor is used to temporarily store data. By using the electrical properties of a semiconductor a transistor is used to transfer data between a bit line and the capacitor corresponding to a control signal (word line). In this case, the property of the semiconductor means that an electric conductivity thereof changes according to its environment. The transistor is composed of a gate region, a source region, and a drain region. A charge is transferred between a source and a drain according to a control signal input to a gate. The charge transfer is achieved through a channel region.

When a general transistor is manufactured on a semiconductor substrate, a gate is formed on the semiconductor substrate, and impurities are doped at both sides of the gate to form a source and a drain. As a data storage capacity of a semiconductor memory device is increased, integration becomes higher and each unit cell is required to become smaller in size. Namely, a design rule of a capacitor and a transistor included in the unit cell is scaled down. Accordingly, a shortened cell transistor channel length causes a short channel effect and Drain Induced Barrier Lower (DIBL) in a general transistor, thereby deteriorating the reliability of an operation. Phenomena occurring due to a reduction in channel length can be solved by keeping a threshold voltage at a level at which a cell transfer can be normally performed. In general, the shorter a transistor channel is, the larger the concentration of doping impurities in the channel.

However, as a design rule is scaled down to less than 100 nm, a doping concentration of a channel region is increased corresponding thereto. This increases an electric field in a Storage Node (SN) junction, thereby deteriorating refresh characteristics of the semiconductor memory device. To solve such a problem, a cell transistor having a three-dimensional channel structure is used. In the cell transistor having a three dimensional channel structure, a channel is longitudinally formed in a vertical direction to secure a channel length under the condition that the design rule is scaled down. That is, although a channel width of a lateral direction is short, a channel length of a vertical direction may be secure. This may reduce a doping concentration of the channel region to prevent the refresh characteristics from being deteriorated.

Furthermore, the higher the degree of integration of a semiconductor device, the shorter the distance between a word line connected to a cell transistor and a bit line. Parasitic capacitance occurring due to this deteriorates an operating margin of a sense amplifier amplifying data to be transferred to a bit line, thereby having a bad influence on the operation reliability of a semiconductor device. To solve such a problem, a buried word line structure is suggested to reduce capacitance between a bit line and a word line. In the buried word line structure, the word line is formed in a recess and not on an upper part of a semiconductor substrate. In the buried word line structure, a conductive material is formed in a recess formed in a semiconductor substrate, and an insulation layer covers an upper part of the conductive material to bury the word line in the semiconductor substrate. The buried word line allows an electric isolation from a bit line formed on a semiconductor substrate on which source/drain are formed to be clearly achieved.

However, in a buried word line (buried gate) structure a leakage current due to Gate Induced Drain Leakage (GIDL) of a semiconductor device can increase between a conductive material (gate electrode) and an N type junction or a storage node contact of an active region. This can cause refresh characteristics of a semiconductor device to deteriorate due to degradation of the GIDL characteristic. To prevent an increase of the leakage current due to the GIDL characteristic, the conductive material (gate electrode) of the buried word line (buried gate) structure may be etched deeper to minimize an overlap area between the storage node contact and the conductive material (gate electrode). The conductive material (gate electrode) of the buried word line (buried gate) structure may be etched deeper to prevent an increase of the leakage current due to the GIDL characteristic. However, this increases resistance of a buried word line (buried gate) and lowers the speed of the semiconductor device.

### BRIEF SUMMARY OF THE INVENTION

Embodiments of the present invention are directed to a semiconductor device and a method for manufacturing the same.

According to an embodiment of the present invention, a method for manufacturing a semiconductor device, includes: burying a conductive material in a semiconductor substrate; firstly etching the conductive material; forming a first insulation layer over the conductive material and the semiconductor substrate; etching the first insulation layer and the conductive material to form a stepped gate; and forming a second insulation layer over the stepped gate and the conductive material.

In accordance with an embodiment of the present invention, a method for manufacturing a semiconductor device, further includes: forming a device isolation region defining an active region at the semiconductor substrate; etching the semiconductor substrate using gate mask; and forming a gate oxide layer over the etched semiconductor substrate.

The active region includes a first active region coupled to a bit line contact and a second active region coupled to a storage node contact.

A height of a conductive material coupled to the bit line contact and contacting with the active region is greater than that of a conductive material connected to the storage node contact and contacting with the active region.

Etching the semiconductor substrate comprises an anisotropic etching process.

Firstly etching the conductive material comprises an etch-back process.

The conductive material includes any of poly silicon, aluminum (Al), tungsten (W), a tungsten nitride (WN) layer, titanium (Ti), a titanium nitride (TiN) layer and a laminate structure of the tungsten (W) and the titanium nitride (TiN) layer.

Forming a stepped gate includes: forming mask exposing the conductive material coupled to the storage node contact and contacting with the active region; and etching the first insulation layer and the conductive material using the mask.

In accordance with an embodiment of the present invention, a method for manufacturing a semiconductor device, further includes: planarizing and etching the second insulation layer until the semiconductor substrate is exposed.

The first insulation layer includes an oxide layer.

The second insulation layer includes a nitride layer.

According to another embodiment of the present invention, a semiconductor device includes: a device isolation region defining an active area at a semiconductor substrate; and a gate provided in the semiconductor substrate, wherein a conductive material of the gate has a stepped part.

The conductive material includes any of poly silicon, aluminum (Al), tungsten (W), a tungsten nitride (WN) layer, titanium (Ti), a titanium nitride (TiN) layer and a laminate structure of the tungsten (W) and the titanium nitride (TiN) layer.

The active region includes a first active region coupled to a bit line contact and a second active region coupled to a storage node contact.

A height of a conductive material coupled to the bit line contact and contacting with the active region is greater than that of a conductive material coupled to the storage node contact and contacting with the active region.

### BRIEF DESCRIPTION OF THE DRAWINGS

FIG. 1a to FIG. 1f are cross-sectional views illustrating a semiconductor device and a method for manufacturing the same.

### DESCRIPTION OF EMBODIMENTS

Embodiments of the present invention are described with reference to the accompanying drawings in detail.

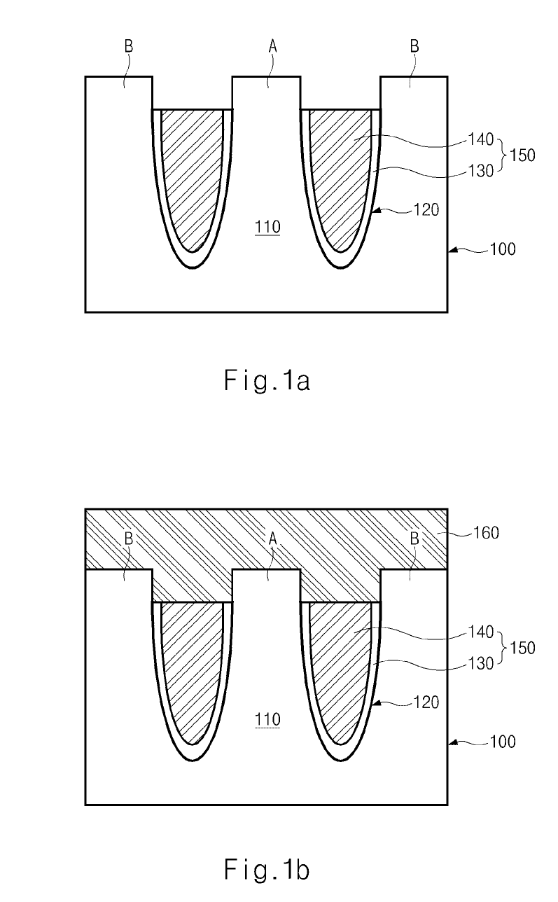

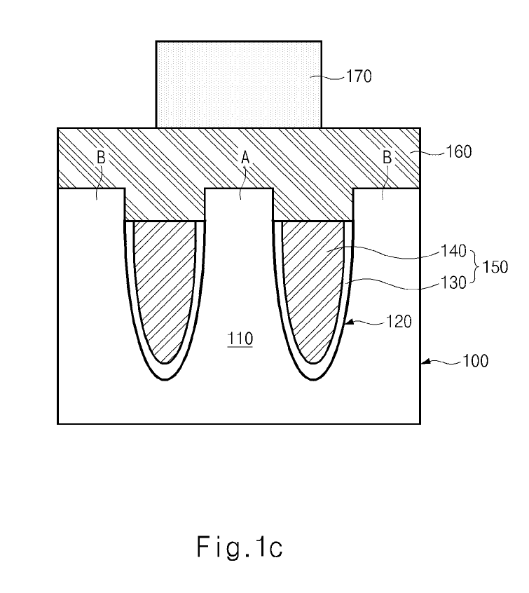

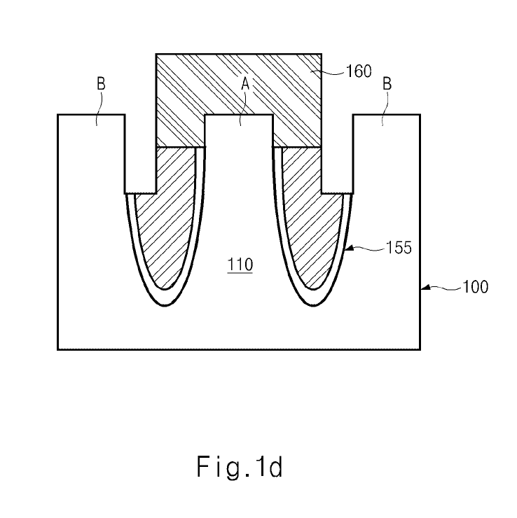

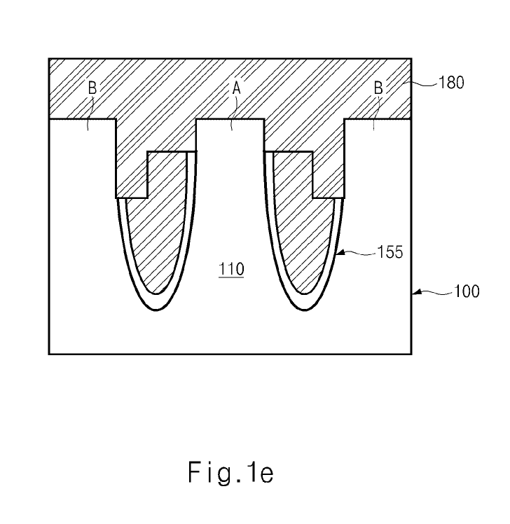

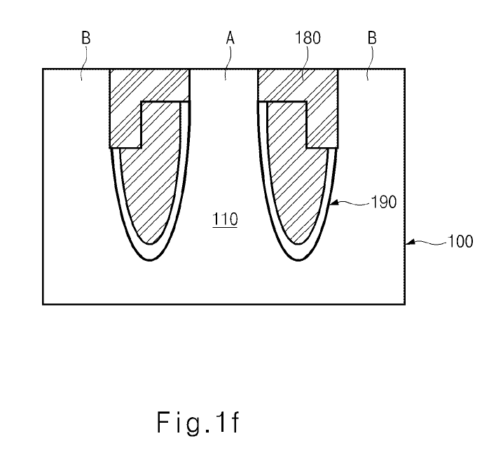

FIG. 1a to FIG. 1f are cross-sectional views illustrating a semiconductor device and a method for manufacturing the same.

Referring to FIG. 1a, a device isolation region (not shown) defining an active region 110 is formed on a semiconductor substrate 100. In this case, the active region may be an island type, a bar type, or a line type. Further, the device isolation region can be formed by a Shallow Trench isolation (STI) process. Here, the active region 110 is defined to be divided into a first active region A connecting with a bit line contact and a second active region B connecting with a storage node contact.

First, a pad insulation layer (not shown) is deposited on the semiconductor substrate 100. The pad insulation layer is composed of a pad oxide layer and a pad nitride layer. Subsequently, a photo resist (not shown) is deposited and an exposure process is performed using a mask defining the active region 110.

Next, a Spin On Dielectric (SOD) material is buried in a trench (not shown) formed by patterning the pad insulation layer and the semiconductor substrate 100, and a planarization etch is performed using a chemical Mechanical Polishing process until the pad insulation layer is exposed, thereby manufacturing the device isolation region.

After formation of the device isolation region, N type impurity ions are implanted on the exposed active region 110. Subsequently, an insulation layer (not shown) or a hard mask layer (not shown) is deposited on an entire surface including the active region 110.

Next, after formation of a photo resist (not shown) on the insulation layer or the hard mask layer (not shown), an exposure process is performed using a mask defining a buried gate to pattern the insulation layer or the hard mask layer. Subsequently, the active layer 110 and the device isolation region are etched using the patterned insulation layer or hard mask layer as an etching mask to form a gate region 120. The etching process forming the gate region 120 may use an anisotropic etching process. Next, a gate oxide layer 130 is deposited over the gate region 120.

After a conductive material 140 is deposited at an entire surface including the gate region 120 on which the gate oxide 130 is formed, the resultant is firstly etched to form a gate pattern 150 separating respective cells. In this case, the first etching may use an etch-back process where the etching depth of the conductive material 140 ranges from 100 Å˜500 Å

In this embodiment the etching depth of the conductive material 140 ranges from 200 Å˜300 Å. Further, the conductive material 140 may include polysilicon, aluminum (Al), tungsten (W), a tungsten nitride (WN) layer, titanium (Ti), a titanium nitride (TiN) layer, or a laminate structure of the tungsten (W) and the titanium nitride (TiN) layer.

Referring to FIG. 1b and FIG. 1c, a first insulation layer 160 is deposited on the gate pattern 150 and the active region 110. In this case, the first insulation layer 160 is formed by an oxide layer.

Subsequently, after formation of a photo resist (not shown) on the first insulation layer 160, a photo resist pattern 170 is formed by an exposure and development processes. The photo resist pattern 170 is formed using a mask which exposes a part of the gate pattern 150 contacting with the active region B connected to a storage node contact. That is, in this embodiment the photo resist pattern 170 is a pattern formed to shield an active region A connected to a bit line contact and a part of the gate pattern 150.

Referring to FIG. 1d, the first insulation layer 160 and the gate pattern 150 are etched using the photo resist pattern 170 as an etching mask to form a gate pattern 155 of an asymmetric structure (having a stepped portion). In the gate pattern 155 of an asymmetric structure, a gate metal material at a sidewall of the active region A connected to the bit line contact and a gate metal material at a sidewall of the active region B connected to the storage node contact has a step difference.

That is, because the gate metal material at a sidewall of the active region A connected to the bit line contact is shielded so as not to be etched due to the photo resist pattern 170, it has a height or a step higher than that of the gate metal material at a sidewall of the active region B connected to the storage node contact. The height or step may reduce gate resistance between the active region A connected to the bit line contact and the gate metal material, and improve Gate Induced Drain Leakage (GIDL) property between the active region B connected to the storage node contact and the gate metal material.

Referring to FIG. 1e and FIG. 1f, a second insulation layer 180 is deposited at an entire surface including the gate pattern 155 of an asymmetric structure. At this time, the second insulation layer 180 is formed by an oxide layer. Next, a planarization etch is performed using a chemical Mechanical Polishing process until the active region 110 is exposed to thereby manufacture the buried gate 190.

As apparent from the above description, the present invention etches a gate metal material at a sidewall of the active region connected to the storage node contact deeper than a gate metal material at a sidewall of the active region connected to the bit line contact in a buried gate structure to prevent GILD and to reduce resistance of a buried gate, thereby improving refresh characteristics of the semiconductor device.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, comprising:
providing a conductive material below a surface of a semiconductor substrate;
etching the conductive material provided below the surface of the semiconductor substrate;
forming a first insulation layer over the conductive material and the semiconductor substrate;
etching the first insulation layer and partially etching the conductive material to form a gate having a step profile; and
forming a second insulation layer over the gate having the step profile.

2. The method of claim 1, further comprising:
forming a device isolation region defining an active region at the semiconductor substrate;
etching the semiconductor substrate using a gate mask; and
forming a gate oxide layer over the etched semiconductor substrate.

3. The method of claim 2, wherein the active region includes a first active region coupled to a bit line contact and a second active region coupled to a storage node contact.

4. The method of claim 3, wherein a height of a conductive material coupled to the bit line contact and contacting with the active region is greater than that of a conductive material connected to the storage node contact and contacting with the active region.

5. The method of claim 2, wherein etching the semiconductor substrate comprises an anisotropic etching process.

6. The method of claim 1, wherein etching the conductive material comprises an etch-back process.

7. The method of claim 1, wherein the conductive material includes any of poly silicon, aluminum (Al), tungsten (W), a tungsten nitride (WN) layer, titanium (Ti), a titanium nitride (TiN) layer and a laminate structure of the tungsten (W) and the titanium nitride (TiN) layer.

8. The method of claim 1, wherein forming the gate having the step profile comprises:
forming mask exposing the conductive material coupled to the storage node contact and contacting with the active region; and
etching the first insulation layer and partially etching the conductive material using the mask.

9. The method of claim 1, further comprising planarizing and etching the second insulation layer until the semiconductor substrate is exposed.

10. The method of claim 1, wherein the first insulation layer includes an oxide layer.

11. The method of claim 1, wherein the second insulation layer includes a nitride layer.

12. A semiconductor device comprising:
a device isolation region defining an active area in a semiconductor substrate; and
a gate provided in a trench defined on the semiconductor substrate, the gate including a conductive material that has a step profile.

13. The semiconductor device of claim 12, wherein the conductive material includes any of poly silicon, aluminum (Al), tungsten (W), a tungsten nitride (WN) layer, titanium (Ti), a titanium nitride (TiN) layer and a laminate structure of the tungsten (W) and the titanium nitride (TiN) layer.

14. The semiconductor device of claim 12, wherein the active region includes a first active region coupled to a bit line contact and a second active region coupled to a storage node contact.

15. The semiconductor device of claim 14, wherein a height of a conductive material coupled to the bit line contact and contacting with the active region is greater than that of a conductive material coupled to the storage node contact and contacting with the active region.

16. A semiconductor device comprising:
a gate pattern formed within a trench defined on a substrate;
a first active region formed at a first side of the gate pattern and coupled to the gate pattern;
a second active region formed at a second side of the gate pattern and electrically coupled to the gate pattern, the second side being on an opposing side of the first side with respect to the gate pattern,
wherein the gate pattern has a first upper surface and a second upper surface that are provided at substantially different heights with respect to a bottom of the trench.

17. The semiconductor device of claim 16, wherein the gate pattern is a buried gate pattern and is spaced apart from the first active region by a first distance D1, and spaced apart from the second active region by a second distance D2, and
wherein the first distance D1 is shorter than the second distance D2.

18. The semiconductor device of claim 17, wherein the first active region is electrically coupled to a bit line and the second active region is electrically coupled to a storage node.

19. The semiconductor device of claim 16, wherein the first upper surface and the second upper surface define a step profile.
